(19) United States
(12) Patent Application Publication
(10) Pub. No.: US 2025/0190146 A1
(43) Pub. Date: Jun. 12, 2025

(54) MEMORY CONTROLLER, METHOD OF CONTROLLING MEMORY CONTROLLER AND MEMORY DEVICE

(71) Applicant: CANON KABUSHIKI KAISHA, Tokyo (JP)

(72) Inventors: NAOKI HIRATA, Kanagawa (JP); DAISUKE SHIRAISHI, Tokyo (JP)

(21) Appl. No.: 18/973,951

(22) Filed: Dec. 9, 2024

(30) Foreign Application Priority Data
Dec. 12, 2023 (JP) 2023-209552

(51) Int. Cl. G06F 3/06

(52) U.S. Cl. CPC G06F 3/0659; G06F 3/0613; G06F 3/0683

(57) ABSTRACT

A memory controller for issuing read and write commands for accessing a plurality of memories that share a data signal, the memory controller comprising: a hold circuit configured to hold access requests for the commands; and a control circuit configured to select an access request from access requests held in the hold circuit and issue a command, wherein the control circuit, in a case where a command is issued to a second memory different to a first memory to which a command was issued immediately previously, controls which command to issue preferentially based on respective predetermined periods set in advance for each set of a type of the command issued immediately previously to the first memory and a type of the command to be issued to the second memory.

### BACKGROUND

### Field of the Disclosure

The present disclosure relates to a memory controller, a method of controlling the memory controller and a memory device, and more particularly, to a technique in which a memory controller, which is connected to a Dynamic Random Access Memory (DRAM), selects an arbitrary memory access request from a plurality of memory access requests, and issues a command.

### Description of the Related Art

A DRAM is commonly used as a main storage device of a computer system. With an increase in the sophistication of functions and performance of computer systems, performance demands for DRAM are increasing, and various methods of memory controllers have been proposed to maximize this performance.

In a case of performing a transfer in a different transfer direction such as a write command after a read command or a read command after a write command, more than in a case where transfer is continued in the same transfer direction, it is necessary to leave open a command interval, which causes a decrease in memory utilization efficiency.

Japanese Patent No. 6950149 discloses determining a priority transfer direction, outputting all transfers in the priority transfer direction from a command queue, and then switching the priority transfer direction to the other transfer direction.

However, the technique described in Japanese Patent No. 6950149 does not mention a case where a memory controller switches which memory to issue a read/write command to in relation to a plurality of memories that share data. For example, in a case where an access destination memory is switched, depending on the type of the command issued immediately previously, it may be even more necessary to leave open a command interval when continuing with a command in the same direction than when issuing a command for a different transfer direction (for example, for a read after a write), which may cause a decrease in memory utilization efficiency.

### SUMMARY

Some embodiments of the present disclosure have been made in view of the above-described problems and provide a technique for suppressing a decrease in utilization efficiency of a memory.

According to one aspect of the present disclosure, there is provided a memory controller for issuing read and write commands for accessing a plurality of memories that share a data signal, the memory controller comprising: a hold circuit configured to hold access requests for the commands; and a control circuit configured to select an access request from access requests held in the hold circuit and issue a command, wherein the control circuit, in a case where a command is issued to a second memory different to a first memory to which a command was issued immediately previously, controls which command to issue preferentially based on respective predetermined periods set in advance for each set of a type of the command issued immediately previously to the first memory and a type of the command to be issued to the second memory.

Further features of various embodiments will become apparent from the following description of exemplary embodiments (with reference to the attached drawings).

### BRIEF DESCRIPTION OF THE DRAWINGS

FIG. 1 is a configuration diagram for a memory controller according to an embodiment.

FIG. 2 is a configuration diagram for an access holding circuit entry according to an embodiment.

FIG. 3 is a configuration diagram for a read/write control circuit according to an embodiment.

FIGS. 4A to 4C are views illustrating an operation example 1 in which a memory access request is selected according to an embodiment.

FIGS. 5A to 5C are views illustrating an operation example 2 in which a memory access request is selected according to an embodiment.

### DESCRIPTION OF THE EMBODIMENTS

Hereinafter, embodiments will be described in detail with reference to the attached drawings. Note, the following embodiments are not intended to limit the scope of every embodiment. Multiple features are described in the embodiments, but limitation is not made to an embodiment that requires all such features, and multiple such features may be combined as appropriate. Furthermore, in the attached drawings, the same reference numerals are given to the same or similar configurations, and redundant description thereof is omitted.

### Embodiments

The present embodiment can be used for various memory controllers that are connected to a DRAM, select a memory access request from a plurality of memory access requests, and issue a command.

### Memory Controller Configuration

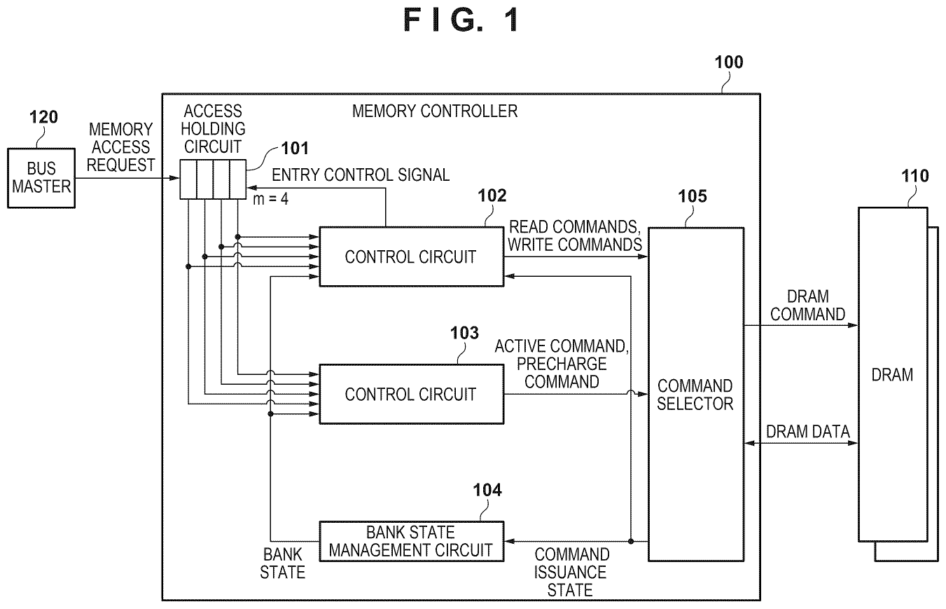

FIG. 1 is a configuration diagram for a memory controller 100 according to an embodiment. The memory controller 100 issues read or write commands to access a plurality of memories sharing a data signal. The memory controller 100 is connected to a DRAM 110 which is constituted by a plurality of banks and a bus master 120. The DRAM 110 is composed of two memory devices (a memory 0 and a memory 1), and the memory 0 and memory 1 share a data signal. In the present embodiment, the configuration is such that a data signal is shared by two DRAMs, but the DRAMs sharing the data signal are not limited to two, and may be three or more. The bus master 120 transmits a memory access request including address information and write data to the memory controller 100. The memory controller 100 generates a DRAM command based on the memory access request received from the bus master 120, and transmits the generated command to one of a plurality of DRAMs 110. Further, the memory controller 100 performs data transfer with the DRAM 110 based on the transmitted DRAM command.

The memory controller 100 includes an access holding circuit 101, a read/write control circuit 102, a page control circuit 103, a bank state management circuit 104, and a command selector 105.

### Operation of the Access Holding Circuit 101

First, the operation of the access holding circuit 101 will be described. The access holding circuit 101 is a buffer that holds a plurality of memory access requests. The access holding circuit 101 is constituted by m (m>=2) entries. Note that the present embodiment does not depend on the number of m.

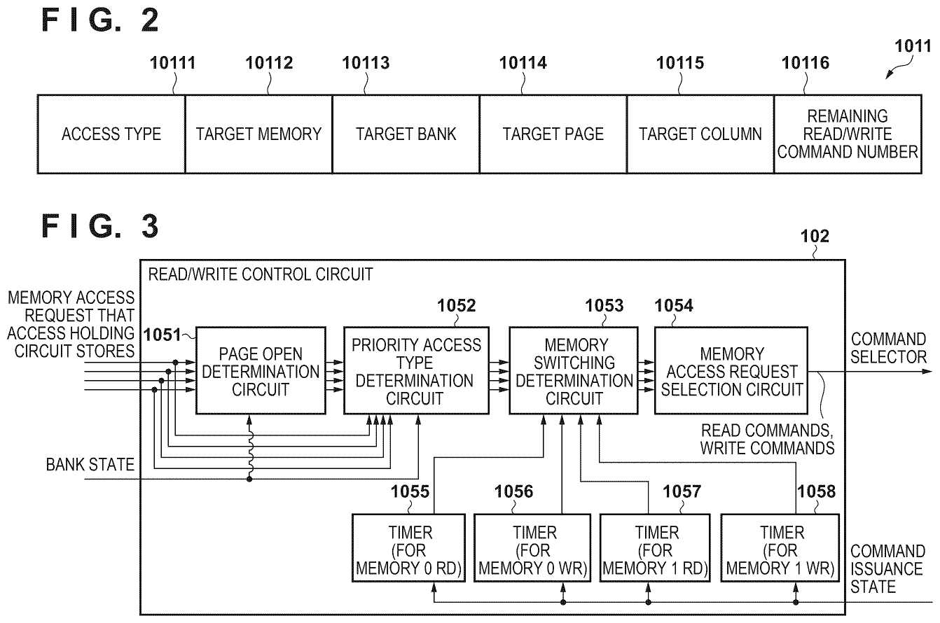

FIG. 2 is a configuration diagram for an access holding circuit entry 1011 according to an embodiment. In the present embodiment, in the access holding circuit 101, there are m access holding circuit entries 1011. As illustrated in FIG. 2, the access holding circuit entry 1011 includes fields 10111 to 10116 which are for access type, target memory, target bank, target page, target column, and the remaining read/write command number. The access holding circuit 101 converts a memory access request received from the bus master 120 so as to correspond to each field, and holds the converted memory access request. The information stored in each field is as follows.

(a) Access type field 10111:

This indicates the access type of the memory access request stored in the entry.

WRITE: The memory access request is for writing (data writing).

READ: The memory access request is for reading (data reading).

(b) Target memory field 10112:

This indicates the memory to be accessed by the memory access request stored in the entry.

(c) Target bank field 10113:

This indicates the bank address to be accessed by the memory access request stored in the entry.

(d) Target page field 10114:

This indicates the page address to be accessed by the memory access request stored in the entry.

(e) Target column field 10115:

This indicates the head column address to be accessed by the memory access request stored in the entry.

(f) Remaining read/write command number field 10116:

This indicates the number of remaining DRAM read/write commands to be executed according to the memory access request stored in the entry.

When a memory access request is stored in the access holding circuit 101, the memory access request is stored in an entry following a rearmost stored memory access request. When a memory access request is read from the access holding circuit 101, it can be read from any entry.

Next, an entry control signal inputted from the read/write control circuit 102 to the access holding circuit 101 will be described. The entry control signal is constituted by an entry number field, a delete field, and an update field. In a case where 1 is set in the delete field, the access holding circuit 101 deletes the entry indicated by the entry number field. In a case where 1 is set in the update field, the access holding circuit 101 updates the column field of the entry indicated by the entry number field to be the head column address, which is to be accessed by the next DRAM command. Also, the remaining read/write command number field is updated to a value obtained by subtracting 1.

### Operation of the Read/Write Control Circuit 102

Next, the operation of the read/write control circuit 102 will be described. The read/write control circuit 102 can refer to all the memory access requests stored in the access holding circuit 101. The read/write control circuit 102, from among the memory access requests stored in the access holding circuit 101, selects a memory access request for which a page to be accessed is open and for which a command issuance wait due to memory switching will not occur. Whether or not the page to be accessed by the memory access request is open is determined from the target memory field 10112, the target bank field 10113, the target page field 10114, and the bank state generated by the bank state management circuit 104, which will be described later, of the access holding circuit entry 1011.

The read/write control circuit 102 generates a read command or a write command from a selected memory access request, and outputs the command to the command selector 105. The read/write control circuit 102 of the present embodiment has a function of selecting memory access requests so as to continuously issue read commands and write commands to the same memory in order to suppress a read/write switching penalty.

Next, a procedure by which the read/write control circuit 102 generates an entry control signal will be described. When the last read command or write command executed according to a memory access request is issued, the processing of the corresponding memory access request is completed. Therefore, the read/write control circuit 102 generates an entry control signal so as to delete the corresponding entry from the access holding circuit 101. On the other hand, in a case where a read command or write command that this not the last is issued, the read/write control circuit 102 generates an entry control signal so as to update the corresponding entry of the access holding circuit 101.

However, in a case where the last read command or write command is issued, it is not necessary to update the corresponding entry. Whether or not the issued read command or write command is the last can be determined based on whether or not the remaining read/write command number field 10116 of the access holding circuit entry 1011 is 1.

### Operation of the Page Control Circuit 103

Next, the operation of the page control circuit 103 will be described. The page control circuit 103 can refer to all of the memory access requests stored in the access holding circuit 101. The input to the page control circuit 103 is a memory access request stored in the access holding circuit 101 and a bank state outputted from the bank state management circuit 104. The page control circuit 103 generates a page control command such as an active command or a precharge command based on the memory access request stored in the access holding circuit 101 and the bank state, and outputs the page control command to the command selector 105.

### Operation of the Bank State Management Circuit 104

Next, the operation of the bank state management circuit 104 will be described. The bank state management circuit 104 updates the bank state based on the command issuance state inputted from the command selector 105. The command issuance state is composed of the type of command issued to the DRAM 110, and the memory, bank, and page for which the command is issued. The bank state includes whether or not a page is open for each bank constituting the DRAM 110 and the address of the page that is open.

### Operation of the Command Selector 105

Finally, the operation of the command selector 105 will be described. The command selector 105 selects one of a read/write command inputted from the read/write control circuit 102 and a page control command inputted from the page control circuit 103 and issues it to the DRAM 110. Although not described in the present embodiment, a command such as refresh may also be selected. Further, the command selector 105 outputs, to the read/write control circuit 102 and the bank state management circuit 104, a command issuance state, which is constituted by a command type of a command issued to the DRAM 110, and a memory, bank, and page for which the command was issued.

### Configuration of the Read/Write Control Circuit 102

FIG. 3 is a configuration diagram for the read/write control circuit 102 according to an embodiment. The read/write control circuit 102 includes a page open determination circuit 1051, a priority access type determination circuit 1052, a memory switching determination circuit 1053, a memory access request selection circuit 1054, and timers 1055, 1056, 1057, and 1058.

The timer 1055 corresponds to a read command for the memory 0 of the plurality of DRAMs 110, and the timer 1056 corresponds to a write command for the memory 0. The timer 1057 corresponds to a read command of the memory 1 of the plurality of the DRAM 110, and the timer 1058 corresponds to a write command of the memory 1.

The page open determination circuit 1051 determines, based on the bank state, whether or not the target bank of the target memory has opened the target page for each of the memory access requests stored in the access holding circuit 101. The page open determination circuit 1051 outputs, to the priority access type determination circuit 1052, only the memory access requests for which the target page is open among the memory access requests stored in the access holding circuit 101, and masks other memory access requests.

The priority access type determination circuit 1052 determines whether or not the access type corresponds to a priority access type for each of the memory access requests outputted by the page open determination circuit 1051. The priority access type is generated by the priority access type determination circuit 1052 based on a memory access request stored in the access holding circuit 101 and the bank state, and indicates whether it is a period in which read commands or write commands are to be issued preferentially. The priority access type determination circuit 1052 outputs to the memory switching determination circuit 1053 only the memory access requests corresponding to the priority access type for each of the memory access requests outputted by the page open determination circuit 1051, and masks all other memory access requests.

In a case where the command issuance state outputted from the command selector 105 indicates the issuance of a read or write command to a memory other than the memory 0, the timer 1055 sets a period in which a read command cannot be issued to a different memory after the issuance of a command. Note that the period to be set differs depending on whether the command issued from the command selector 105 is a read or a write. The value of the timer 1055 is decremented according to the elapsation of time except at the time of setting, and stops at 0. In the present embodiment, a period in which a read command cannot be issued to a different memory after a read command or a write command is issued to a certain memory is set in the timer, but some embodiments are not limited thereto. A period during which a read/write command cannot be issued to a different memory after a read/write command is issued to a certain memory may be increased or decreased, whereby the relationship between the frequency of the memory switching and the memory access request waiting time can be adjusted.

In a case where the command issuance state outputted from the command selector 105 indicates the issuance of a read or write command to anything other than the memory 0, the timer 1056 sets a period in which a write command cannot be issued to a memory other than a particular memory after the issuance of the command. Other behavior is the same as that of the timer 1055.

In a case where the command issuance state outputted from the command selector 105 indicates the issuance of a read or write command to anything other than the memory 1, the timer 1057 sets the period in which, after the issuance of the command a particular memory, a read command cannot be issued to a different memory. Other behavior is the same as that of the timer 1055.

In a case where the command issuance state outputted from the command selector 105 indicates the issuance of a read or write command to anything other than the memory 1, the timer 1058 sets the period in which, after the issuance of the command to a particular memory, a write command cannot be issued to a different memory. Other behavior is the same as that of the timer 1055.

The memory switching determination circuit 1053 determines whether or not waiting for a timing constraint for memory switching is necessary for each of the memory access requests outputted by the priority access type determination circuit 1052. Whether or not it is necessary to wait for a timing constraint for memory switching for a memory access request is determined based on whether or not the value of the timer corresponding to the target memory of the memory access request is other than 0. When the target memory of the memory access request is the memory 0 and it is a read, the timer 1055 is referred to. When the target memory of the memory access request is the memory 0 and it is a write, the timer 1056 is referred to. When the target memory of the memory access request is the memory 1 and it is a read, the timer 1057 is referred to. When the target memory of the memory access request is the memory 1 and it is a write, the value of the timer 1058 is referred to.

The memory switching determination circuit 1053 outputs, to the memory access request selection circuit 1054, only memory access requests for which no command issuance wait due to memory switching will occur, out of the memory access requests outputted by the priority access type determination circuit 1052. A memory access request for which a command issuance wait will occur is masked.

The memory access request selection circuit 1054 selects an arbitrary memory access request from the memory access requests outputted by the memory switching determination circuit 1053. Then, a read command or a write command of the selected memory access request is generated and outputted to the command selector 105.

### Operation

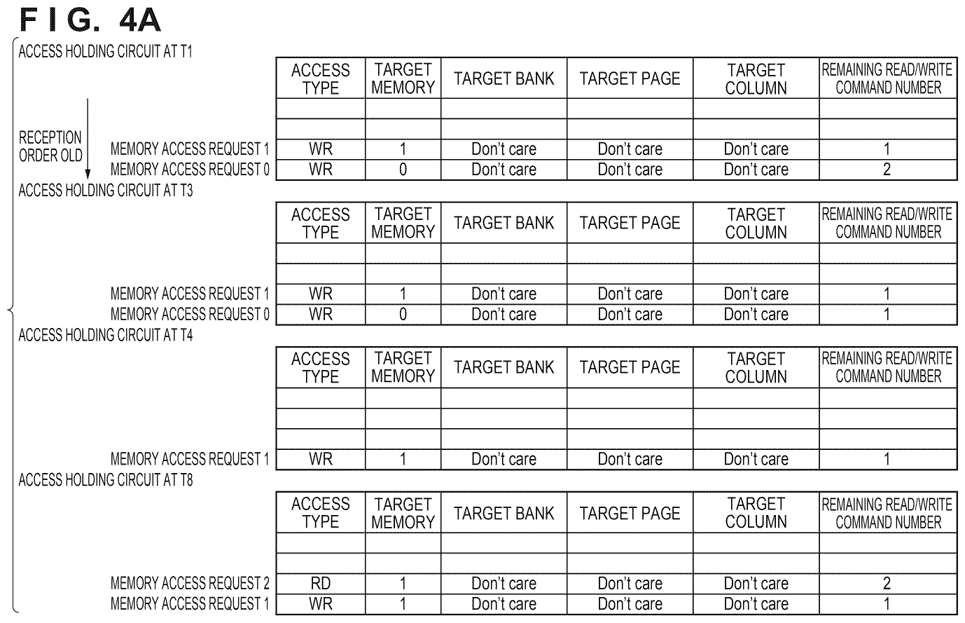

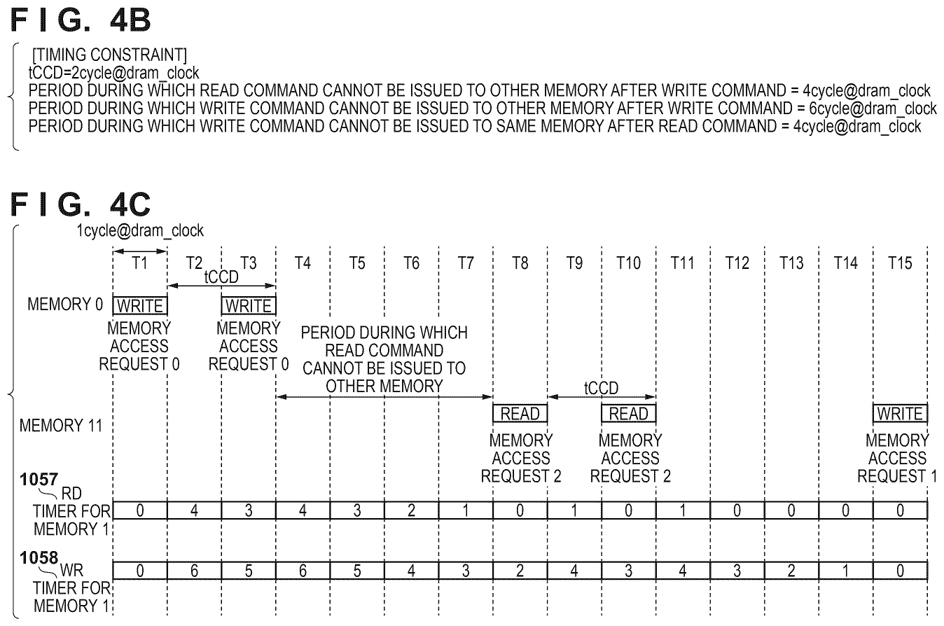

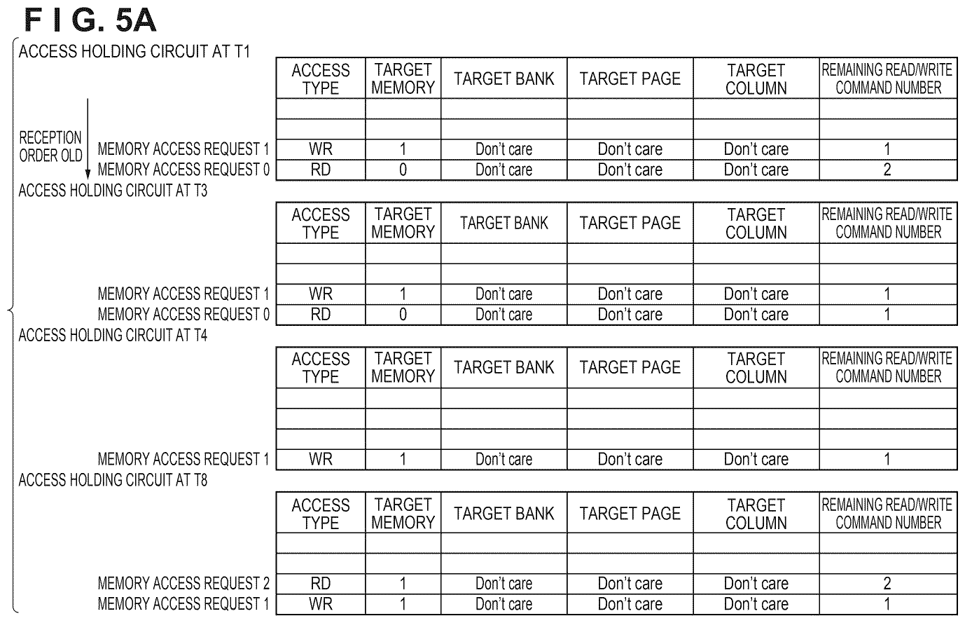

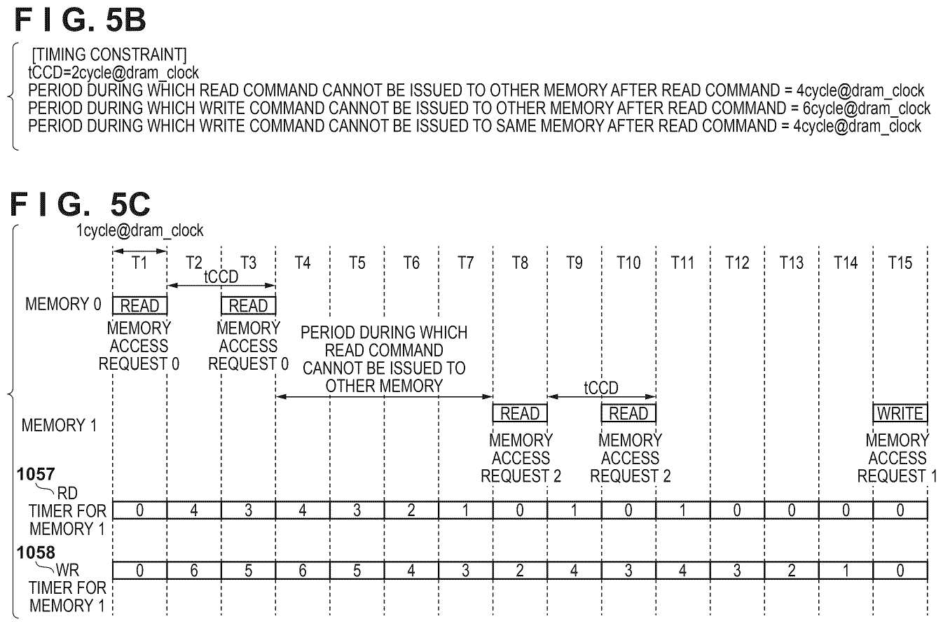

FIGS. 4A to 4C and FIGS. 5A to 5C are views illustrating an exemplary operation of selecting a memory access request in the present embodiment. FIGS. 4A to 4C illustrate an exemplary memory access request selection when a read command is issued to another memory after a write command, according to the present embodiment. FIGS. 5A to 5C illustrate an exemplary memory access request selection when a read command is issued to another memory after a read command, according to the present embodiment.

FIG. 4A and FIG. 5A illustrate the state of the access holding circuit 101 in a given cycle. For the sake of explanation, the memory access requests 0 to 2 and the identifiers are assigned to each of the memory access requests held in the access holding circuit 101.

FIG. 4B and FIG. 5B illustrate cycles (predetermined periods) that should be opened between respective commands. The timing constraints illustrated in FIG. 4B are as follows,
tCCD=2cycle@dram_clock.
The period in which a read command cannot be issued after a write command to a different memory=4cycle@dram_clock.
The period in which a write command cannot be issued after a write command to a different memory=6cycle@dram_clock.
The period in which a write command cannot be issued after a read command to the same memory=4cycle@dram_clock.

Meanwhile, the timing constraints illustrated in FIG. 5B are as follows . . .
tCCD=2cycle@dram_clock.
The period in which a read command cannot be issued after a read command to a different memory=4cycle@dram_clock.
The period in which a write command cannot be issued after a read command to a different memory=6cycle@dram_clock.
The period in which a write command cannot be issued after a read command to the same memory=4cycle@dram_clock.

FIG. 4C and FIG. 5C illustrate, in chronological order, a command issuance state for the memory 0 and the memory 1 of the DRAM 110 and count values of an RD timer 1057 for the memory 1 and a WR timer 1058 for the memory 1. As a premise of these operation examples, it is assumed that the target bank of the target memory has opened the target page for a memory access request held in the access holding circuit 101.

First, using FIGS. 4A to 4C, an exemplary memory access request selection when a read command is issued to another memory after a write command will be described.

In T1, a memory access request 0 having a relatively older reception order and a memory access request 1 having a relatively newer reception order are held. In the memory access request 0, the access type=WR, the target memory=0, the target bank=“don't care”, the target page=“don't care”, the target column=“don't care”, and the remaining read/write command number=2. In the memory access request 1, the access type=WR, the target memory=1, the target bank=“don't care”, the target page=“don't care”, the target column=“don't care”, and the remaining read/write command number=1.

In T1, the read/write control circuit 102 can select either the write memory access request 0 which is for the memory 0 or the write memory access request 1 which is for the memory 1. In this operation example, it is assumed that a write command for the previously received memory access request 0 is issued. Thus, the RD timer 1057 for the memory 1 sets the period (4 cycles) during which a read command cannot be issued to a different memory after a read command is issued to a certain memory, and starts decrementing. Also, the WR timer 1058 for the memory 1 similarly sets the period (6 cycles) during which a write command cannot be issued to a different memory after a read command is issued to a certain memory, and starts decrementing.

In T3, since the timer 1057 and the timer 1058 are not 0, the memory access request 1 is masked, and the read/write control circuit 102 selects the memory access request 0. More specifically, since the memory access request 1 is a write targeting the memory 1, the WR timer 1058 for the memory 1 is referred to. Since the timer 1058 is not 0, the memory access request 1 is masked, and the read/write control circuit 102 selects the memory access request 0.

In the time from T4 to T7, only the memory access request 1 is held in the access holding circuit 101. However, since the timer 1057 and the timer 1058 are not 0, the memory access request 1 is masked, and the read/write control circuit 102 does not select the memory access request. More specifically, since the memory access request 1 is a write targeting the memory 1, the WR timer 1058 for the memory 1 is referred to. Since the timer 1058 is not 0, the memory access request 1 is masked. Further, since there is no other memory access request, the read/write control circuit 102 does not select a memory access request.

Assume that, in T8, a read memory access request 2 which is for the memory 1 is stored in the access holding circuit 101. Since the timer 1058 is not 0, the memory access request 1 is masked. However, since the RD timer 1057 for the memory 1 is 0, the read/write control circuit 102 selects the read memory access request 2, which is for the memory 1. Thereafter, in T15, the WR timer 1058 for the memory 1 becomes 0, the masking of the memory access request 1 is cancelled, and the read/write control circuit 102 selects the memory access request 1.

Next, using FIGS. 5A to 5C, an exemplary memory access request selection when a read command is issued to another memory after a read command will be described.

In T1, a memory access request 0 having a relatively older reception order and a memory access request 1 having a relatively newer reception order are held. In the memory access request 0, the access type=RD, the target memory=0, the target bank=“don't care”, the target page=“don't care”, the target column=“don't care”, and the remaining read/write command number=2. In the memory access request 1, the access type=WR, the target memory=1, the target bank=“don't care”, the target page=“don't care”, the target column=“don't care”, and the remaining read/write command number=1.

In T1, the read/write control circuit 102 can select either the write memory access request 0 which is for the memory 0 or the write memory access request 1 which is for the memory 1. In this operation example, it is assumed that a read command for the previously received memory access request 0 is issued. Thus, the RD timer 1057 for the memory 1 sets the period (4 cycles) during which a read command cannot be issued to a different memory after a read command is issued to a certain memory, and starts decrementing. Also, the WR timer 1058 for the memory 1 similarly sets the period (6 cycles) during which a write command cannot be issued to a different memory after a read command is issued to a certain memory, and starts decrementing.

In T3, since the timer 1057 and the timer 1058 are not 0, the memory access request 1 is masked, and the read/write control circuit 102 selects the memory access request 0. More specifically, since the memory access request 1 is a write targeting the memory 1, the WR timer 1058 for the memory 1 is referred to. Also, since the timer 1058 is not 0, the memory access request 1 is masked, and the read/write control circuit 102 selects the memory access request 0.

In the time from T4 to T7, only the memory access request 1 is held in the access holding circuit 101. However, since the timer 1057 and the timer 1058 are not 0, the memory access request 1 is masked, and the read/write control circuit 102 does not select the memory access request. More specifically, since the memory access request 1 is a write targeting the memory 1, the WR timer 1058 for the memory 1 is referred to. Since the timer 1058 is not 0, the memory access request 1 is masked. Further, since there is no other memory access request, the read/write control circuit 102 does not select a memory access request.

Assume that, in T8, a read memory access request 2, which is for the memory 1, is stored in the access holding circuit 101. Since the timer 1058 is not 0, the memory access request 1 is masked. However, since the RD timer 1057 for the memory 1 is 0, the read/write control circuit 102 selects the read memory access request 2, which is for the memory 1. Thereafter, in T15, the WR timer 1058 for the memory 1 becomes 0, the masking of the memory access request 1 is cancelled, and the read/write control circuit 102 selects the memory access request 1.

As described above, in the present embodiment, in a case where a command is issued to a second memory different from a first memory to which the command was issued immediately previously, the read/write control circuit 102 controls which command to issue preferentially based on respective predetermined periods set in advance for each set of a type of the command issued immediately previously to the first memory and a type of the command issued to the second memory. For example, a command corresponding to a shortest predetermined period is issued preferentially after the lapse of the shortest predetermined period from the immediately previous command issuance.

In a case where a command is issued to the second memory different from the first memory to which a command was issued immediately previously, the read/write control circuit 102 may issue a read command preferentially to a write command. As illustrated in FIG. 4B and FIG. 5B, in a case where the immediately previous command was a read command and a read command is to be issued to a different memory, the cycle time is four cycles. Also, in a case where the immediately previous command was a read command and a write command is to be issued to a different memory, the cycle time is six cycles. Since 6 cycles>4 cycles, the read command is prioritized over the write command. Similarly, in a case where the immediately previous command was a write command and a read command is to be issued to a different memory, the cycle time is four cycles. Also, in a case where the immediately previous command was a write command and a write command is to be issued to a different memory, the cycle time is six cycles. Since 6 cycles>4 cycles, the read command is prioritized over the write command in such a case.

In other words, in a case where a read command is issued to the second memory different from the first memory to which a write command was issued immediately previously, the read/write control circuit 102 performs control so as to issue a read command to the second memory in response to a lapse of a predetermined period (for example, four cycles) from the issuance of the write command. In a case where a write command is issued to the second memory different from the first memory to which a write command was issued immediately previously, control is performed so as to issue a write command to the second memory in response to a lapse of a predetermined period (for example, six cycles) from the issuance of the write command.

Also, in a case where a read command is issued to the second memory different from the first memory to which a read command was issued immediately previously, the read/write control circuit 102 performs control so as to issue the read command to the second memory in response to a lapse of a predetermined period (for example, four cycles) from the issuance of the read command. Also, in a case where a read command is issued to the second memory different from the first memory to which a write command was issued immediately previously, control is performed so as to issue the write command to the second memory in response to a lapse of a predetermined period (for example, six cycles) from the issuance of the read command.

As described above, in the present embodiment, in a case where switching of the access destination memory occurs, a command in a transfer direction (write→read, read→write, etc.) having a shorter command interval is preferentially issued in accordance with the type of the command (write, read) issued immediately previously. That is, a memory access request with a short command issuance wait time due to the switching of the memory is issued preferentially. This makes it possible to suppress a decrease in memory utilization efficiency.

### Modification

When issuing a read command or a write command, the read/write control circuit 102 may perform control so as to preferentially issue a command having a shortest predetermined period among (1) a predetermined period (a penalty period in which a command cannot be selected) set for different memory and different transfer directions, (2) a predetermined period set for different memory and the same transfer direction, (3) a predetermined period set for the same memory and different transfer directions, and (4) a predetermined period set for the same memory and the same transfer direction.

For example, the predetermined period set for different memory and different transfer directions may be nine cycles, and the predetermined period set for different memory and the same transfer direction (for example, write→write) may be 13 cycles. Also, the predetermined period set for the same memory and different transfer directions may be 23 cycles, and the predetermined period set for the same memory and the same transfer direction (for example, write→write) may be four cycles.

According to the present disclosure, is becomes possible to suppress a decrease in memory utilization efficiency.

### Other Embodiments

Embodiment(s) of the present disclosure can also be realized by a computer of a system or apparatus that reads out and executes computer-executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer-executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer-executable instructions. The computer-executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has described exemplary embodiments, it is to be understood that some embodiments are not limited to the disclosed exemplary embodiments. The scope of the following claims is to be accorded the broadest interpretation so as to encompass all such modifications and equivalent structures and functions.

This application claims priority to Japanese Patent Application No. 2023-209552, which was filed on Dec. 12, 2023 and which is hereby incorporated by reference herein in its entirety.

What is claimed is:

1. A memory controller for issuing read and write commands for accessing a plurality of memories that share a data signal, the memory controller comprising:
a hold circuit configured to hold access requests for the commands; and
a control circuit configured to select an access request from access requests held in the hold circuit and issue a command, wherein
the control circuit, in a case where a command is issued to a second memory different to a first memory to which a command was issued immediately previously, controls which command to issue preferentially based on respective predetermined periods set in advance for each set of a type of the command issued immediately previously to the first memory and a type of the command to be issued to the second memory.

2. The memory controller according to claim 1, wherein the control circuit, in a case where a command is issued to the second memory, which is different from the first memory to which a command was issued immediately previously, preferentially issues a command corresponding to a shortest predetermined period among predetermined periods set in advance after the shortest predetermined period has elapsed from the immediately previous issuance of a command.

3. The memory controller according to claim 1, wherein the control circuit, in a case where a command is issued to the second memory different from the first memory to which a command was issued immediately previously, issues a read command preferentially to a write command.

4. The memory controller according to claim 1, wherein the control circuit, in a case where a write command or a read command is issued to the second memory, which is different from the first memory, to which a write command was issued immediately previously, issues a read command preferentially to a write command.

5. The memory controller according to claim 1, wherein the control circuit, in a case where a write command or a read command is issued to the second memory, which is different from the first memory, to which a read command was issued immediately previously, issues a read command preferentially to a write command.

6. The memory controller according to claim 1, wherein
the control circuit performs control to,
in a case where a read command is issued to the second memory, which is different from the first memory, to which a write command was issued immediately previously, issue the read command to the second memory in response to a lapse of a first predetermined period from the issuance of the write command, and
in a case where a write command is issued to the second memory, which is different from the first memory, to which a write command was issued immediately previously, issue the write command to the second memory in response to a lapse of a second predetermined period from the issuance of the write command, and
the second predetermined period is longer than the first predetermined period.

7. The memory controller according to claim 1, wherein the control circuit, in a case where a write command is issued to the first memory, to which a read command was issued immediately previously, issue the write command to the first memory in response to a lapse of a third predetermined period from the issuance of the read command.

8. The memory controller according to claim 1, wherein the control circuit performs control to,
in a case where a read command is issued to the second memory, which is different from the first memory, to which a read command was issued immediately previously, issue the read command to the second memory in response to a lapse of a fourth predetermined period from the issuance of the read command, and
in a case where a write command is issued to the second memory, which is different from the first memory, to which a read command was issued immediately previously, issue the write command to the second memory in response to a lapse of a fifth predetermined period from the issuance of the read command, and
the fifth predetermined period is longer than the fourth predetermined period.

9. The memory controller according to claim 1, wherein the control circuit, in a case where a write command is issued to the first memory, to which a read command was issued immediately previously, issues the write command to the first memory in response to a lapse of a sixth predetermined period from the issuance of the read command.

10. A method for controlling a memory controller for issuing read and write commands for accessing a plurality of memories that share a data signal, the method comprising:
holding, in a hold circuit, access requests for the commands; and
performing control to select an access request from access requests held in the hold circuit and issue a command, wherein
in the control, in a case where a command is issued to a second memory different to a first memory to which a command was issued immediately previously, which command is issued preferentially is controlled based on respective predetermined periods set in advance for each set of a type of command issued immediately previously to the first memory and a type of the command to be issued to the second memory.

11. A memory device comprising:
a plurality of memories that share a data signal; and
a memory controller for issuing read and write commands for accessing the plurality of memories, the controller comprising:
a hold circuit configured to hold access requests for the commands; and
a control circuit configured to select an access request from access requests held in the hold circuit and issue a command, wherein
the control circuit, in a case where a command is issued to a second memory different to a first memory to which a command was issued immediately previously, controls which command to issue preferentially based on respective predetermined periods set in advance for each set of a type of the command issued immediately previously to the first memory and a type of the command to be issued to the second memory.
